(19) United States
(12) Patent Application Publication
(10) Pub. No.: US 2010/0186817 A1
(43) Pub. Date: Jul. 29, 2010

(54) Light Intensity Display Apparatus and Application Thereof

(76) Inventors: Shih-Hui CHEN, Taoyuan Hsieh (TW); Chin-Tien Lin, Taoyuan Hsieh (TW)

Correspondence Address: Jackson Intellectual Property Group PLLC, 106 Starvale Lane, Shipman, VA, 22971, US

(21) Appl. No.: 12/173,915

(22) Filed: Jul. 16, 2008

(30) Foreign Application Priority Data
May 2, 2008 (TW) 097202608

(51) Int. Cl. H01L 31/00; G01J 1/44; G01J 1/04

(52) U.S. Cl. 136/259; 356/226

(57) ABSTRACT

A light intensity display apparatus includes a light guide module, a photosensing module, a processing module, a display module and a box for containing various components. The light guide module is provided for receiving a light source and transmitting the light source to a photosensing module. The light signal is converted into an electric signal, and the processing module receives the electric signal, determines a light intensity according to the electric signal, and transmits the light intensity to the display module for displaying the light intensity.

### BACKGROUND OF THE INVENTION

(a) Field of the Invention

The present invention relates to a light intensity display apparatus, and more particularly to a display apparatus for indicating a light intensity by a graphic, quantified or sound form, and the display apparatus can be applied in an optical electric conversion system.

(b) Description of the Related Art

As natural resources such as petroleum and coal are exhausted gradually, the access and use of energy become difficult, and each country is facing green energy related issues including environmental protection and resource recycle, and energy policies of different countries in the world encourage solar industries to engage in research and development of solar energy. After years of efforts, researchers and manufacturers developed a solar plate for collecting sunlight and a solar battery for converting light energy into electric energy for an extensive use of solar energy in our daily life. Solar appliances such as solar heaters, solar alarms, solar lighthouses, and solar factories and camps are developed, and the design of a solar plate is implemented together with the utility power to compensate the insufficiency of the conventional energy sources and overcome the shortcomings of traditional energy sources that cause pollutions easily. As solar products are used extensively to improve our ecological environment and bring recyclable energy sources, the efficiency of using and converting solar energy is still very low, and thus solar energy researchers spare lots of efforts to improve the conversion efficiency of solar energy.

In a general structure of a solar power device, one or more solar plates are provided for receiving and collecting solar energy and a rechargeable battery is provided for storing electric power and supplying the electric power to other electronic devices, but a general solar appliance used in our daily life usually does not come with an angle adjustable stand for adjusting the angle and direction of receiving light or a light intensity display apparatus, and thus conventional solar appliances cannot maximize the utility of the energy source, and a longer time is usually taken for collecting the required energy.

### SUMMARY OF THE INVENTION

Therefore, it is a primary objective of the present invention to provide a light intensity display apparatus and its application to overcome the aforementioned shortcomings of the prior art.

To achieve the foregoing objective, the present invention provides a display apparatus for displaying a light intensity in a graphic or quantified form, and the display apparatus can be applied in an optical electric conversion system.

The light intensity display apparatus of the present invention comprises a light guide module, a photosensing module, a processing module, a display module and a box for containing various components, wherein the light guide module is provided for receiving a light source, and the light source is transmitted to the photosensing module for converting a light signal into an electric signal, and the processing module is provided for receiving the electric signal, determining light intensity according to the electric signal, and transmitting the light intensity to the display module for the display of the light intensity.

Another objective of the present invention is to provide a display module further comprising a plurality of direction indicating elements provided for users to adjust the angle and direction of receiving light and improve the utility of the light source.

### BRIEF DESCRIPTION OF THE DRAWINGS

FIG. 1 is a perspective view of a light intensity display apparatus in accordance with the present invention;

FIG. 2 is a schematic view of a light intensity display apparatus in accordance with the present invention;

FIG. 3 is a structural block diagram of a light intensity display apparatus in accordance with the present invention;

FIG. 4 is a perspective view of an optical electric conversion system in accordance with the present invention;

FIG. 5 is a perspective view of another optical electric conversion system in accordance with the present invention; and

FIG. 6 is a perspective view of a further optical electric conversion system in accordance with the present invention.

### DETAILED DESCRIPTION OF THE PREFERRED EMBODIMENTS

To make it easy for our examiner to understand the structural assembly and the overall operating method of the present invention, preferred embodiments together with related drawings are used for the detailed description of the present invention as follows:

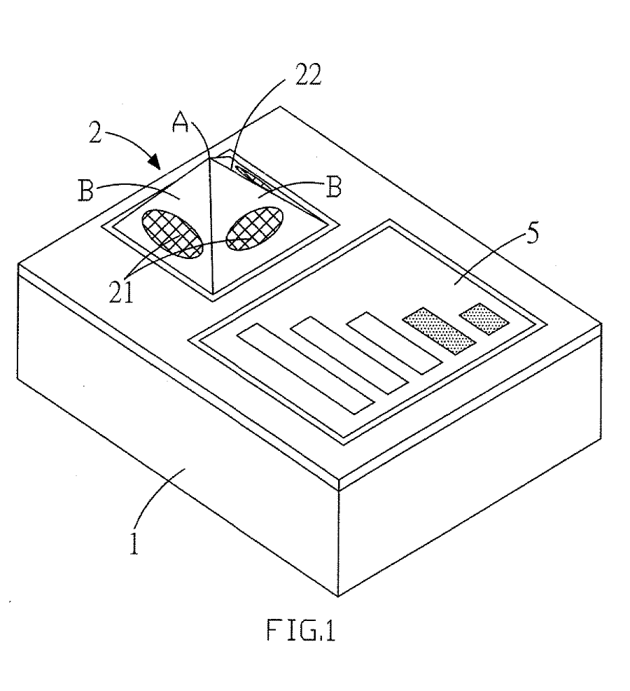

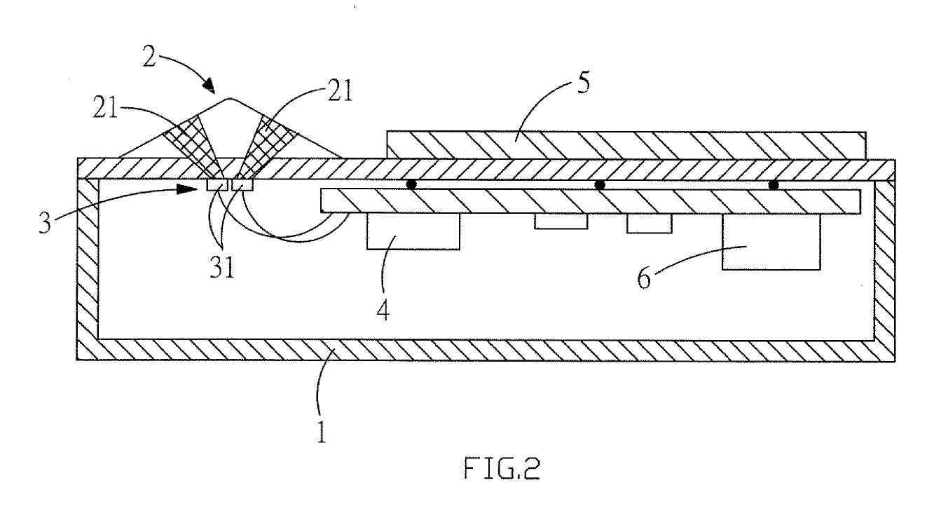

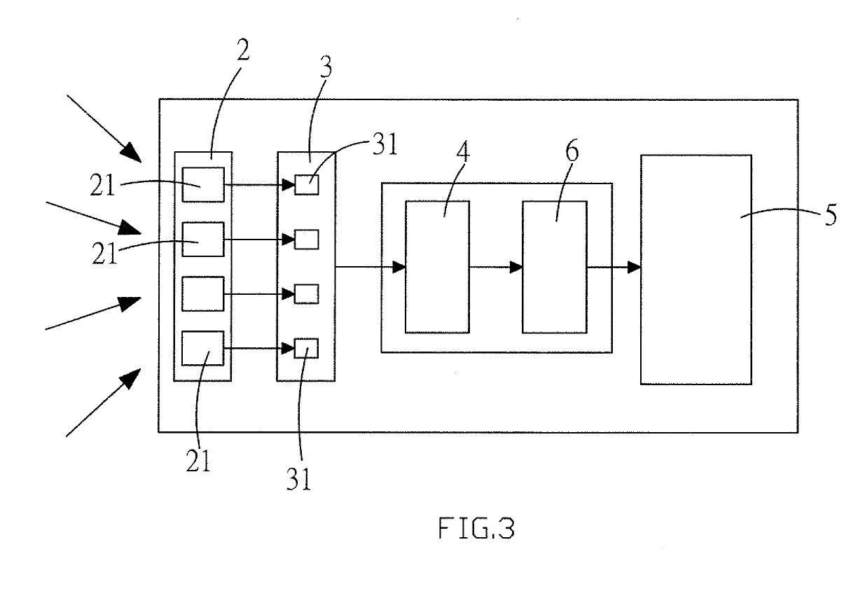

With reference to FIGS. 1 to 3 for a light intensity display apparatus and its application in accordance with the present invention, the light intensity display apparatus comprises:

a box 1, for containing each component module;

a light guide module 2, installed on the box 1, for receiving a light source, and including one or more light guide bodies 21, and an n-sided pyramid, wherein n is greater than or equal to 3, and the n-sided pyramid is a quadrangular pyramid 22 as shown in the figures, and the quadrangular pyramid 22 has a vertex A and four sides B, and each light guide body 21 is installed on each side B, such that each light guide body 21 is situated at a different direction; for example, the four light guide bodies 21 can be disposed in four directions such as East, West, South and North respectively;

a photosensing module 3, installed in the box 1, and having a side coupled to the light guide module 2, and another side coupled to a processing module 4, wherein the photosensing module 3 includes one or more photosensors 31, and each photosensor 31 is coupled to the light guide body 21;

the processing module 4, with a side coupled to the photosensing module 3, and another side coupled to a display module 5;

the display module 5, being installed on the box 1, and coupled to the processing module 4, for displaying a light intensity;

a display device driving module 6, for connecting the processing module 4 and the display module 5.

During use, a plurality of light guide bodies 21 installed in the light guide module 2 receive a light source, and a plurality of photosensors 31 connected to each light guide body 21 sense a light signal received by the light guide module 2. After the light signal is converted into an electric signal, the electric signal is transmitted to the processing module 4, and the processing module 4 receives the electric signal and determines the light intensity according to the electric signal, and finally the display device driving module 6 transmits a determination result to the display module 5 for the display of the light intensity, so that users can know about the light intensity at their location.

The display module can be a graphic indicating element, a text indicating element, a sound indicating element, a color indicating element, a light indicating element or any combination of the above. In a preferred embodiment as shown in FIG. 1, the display module 5 can be a graphic indicating element provided for indicating the light intensity in a graphic display form, so that users can know about the light intensity quickly and clearly.

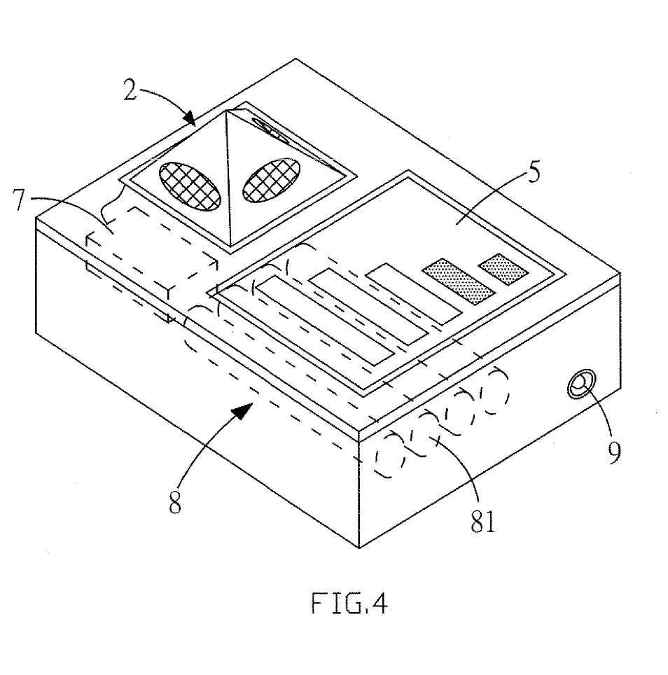

The light intensity display apparatus of the invention can be applied in an optical electric conversion system, and the light intensity apparatus comprises: an optical electric conversion module 7, a battery module 8 and at least one output port 9 as shown in FIG. 4, wherein the optical electric conversion module 7 is coupled to the light guide module 2, for converting the light source into electric energy, and the battery module 8 is coupled to the optical electric conversion module 7, and the battery module 8 includes a plurality of rechargeable batteries 81 for storing the converted electric energy into each rechargeable battery 81, and the output port 9 is provided for supplying the electric power to other electronic devices, and the display module 5 also displays the light intensity.

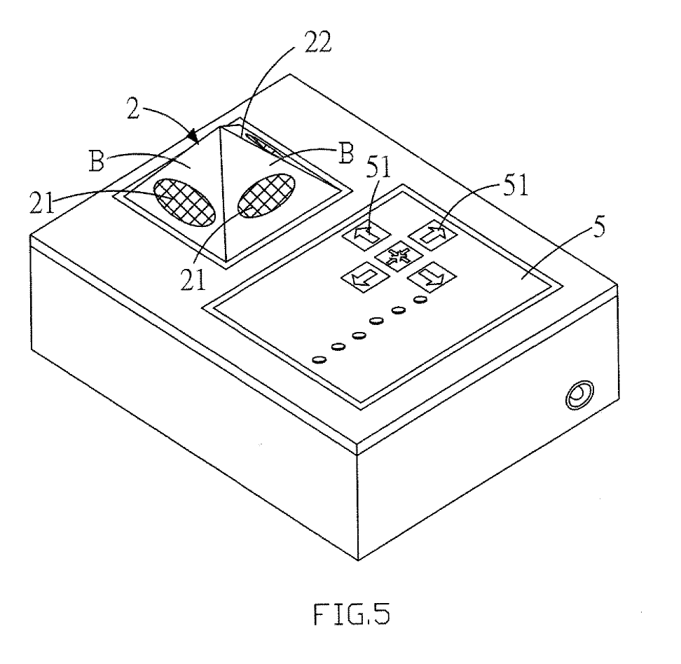

The display module 5 further includes a plurality of direction indicating elements 51 as shown in FIG. 5, and each direction indicating element 51 is extended in a direction towards each corresponding side B of the quadrangular pyramid 22 in accordance with the preferred embodiment as shown in the figure, and the direction indicating elements 51 point at four directions such as East, West, South and North respectively. In other words, if the direction indicating element 51 indicates that the light guide body 21 is pointing at a direction, namely East, then the light guide body 21 situated in the East direction and the connected photosensor sense a stronger light. Now, users can move the entire optical electric conversion system towards the East to adjust the light receiving angle and direction to achieve the best receiving angle, such that the optical electric conversion system can receive a stronger light to improve the utility of the light source. Of course, the display module 5 can be a combination of a text indicating element and a light indicating element as shown in the figure.

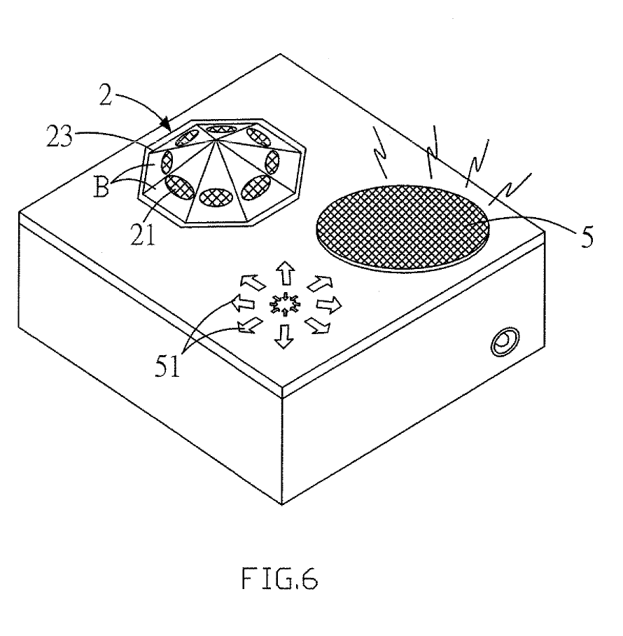

The light guide module 2 can be an octangular pyramid 23 as shown in FIG. 6, and each light guide body 21 is disposed on each side B and the direction indicating element 51 corresponding to each light guide body 21 is pointing at one of the eight different directions to provide a more precise moving direction, and the display module 5 can be a sound indicating element.

It is noteworthy to point out that the present invention has the following advantages:

1. The present invention converts a light intensity into a graphic, quantified display or sound form of display, such that users can know about the light intensity of their location quickly and easily.

2. Users can change the angle to obtain a better position of receiving light according to the displayed light intensity.

3. The light intensity display apparatus can be applied in an optical electric conversion system and used as a power supply device.

4. The invention further includes a direction indicating element provided for users to adjust the best angle and direction of receiving light in order to maximize the utility of the light source.

While the invention is described in some detail hereinbelow with reference to certain illustrated embodiments, it is to be understood that there is no intent to limit it to those embodiments. On the contrary, the aim is to cover all modifications, alternatives and equivalents falling within the spirit and scope of the invention as defined by the appended claims.

I claim:

1. A light intensity display apparatus, comprising:
a box, for containing each component module;
a light guide module, installed on the box, for receiving a light source;
a photosensing module, installed in the photosensing module, and a side of the photosensing module being coupled to the light guide module, and another side of the photosensing module being coupled to a processing module, and the photosensing module being provided for sensing a light signal received by the light guide module, and converting the light signal into an electric signal;
a processing module, having a side coupled to the photosensing module, and another side coupled to the display module, and the processing module being provided for receiving the electric signal, and determining a light intensity according to the electric signal; and
a display module, installed on the box, and coupled to the processing module, for displaying the light intensity.

2. The light intensity display apparatus of claim 1, wherein the light guide module includes one or more light guide bodies.

3. The light intensity display apparatus of claim 2, wherein the photosensing module includes one or more photosensors and each photosensor is coupled to the light guide body.

4. The light intensity display apparatus of claim 1, wherein the light guide module includes a plurality of light guide bodies, and each light guide body is disposed at a different direction.

5. The light intensity display apparatus of claim 4, wherein the light guide module further includes an n-sided pyramid, and n is greater than or equal to 3.

6. The light intensity display apparatus of claim 5, wherein the n-sided pyramid has a vertex and n sides, and each light guide body is disposed on each side.

7. The light intensity display apparatus of claim 5, wherein the display module further includes a plurality of direction indicating elements, and each direction indicating element is extended in a direction corresponding to each corresponding side.

8. The light intensity display apparatus of claim 4, wherein the display module further includes a plurality of direction indicating elements, and each direction indicating element corresponds to the direction of each corresponding light guide body.

9. The light intensity display apparatus of claim 1, wherein the light intensity display apparatus further includes a display device driving module for connecting the processing module and the display module.

10. An optical electric conversion system, comprising:
a light intensity display apparatus as recited in claim 1;
an optical electric conversion module, coupled to the light guide module, for converting a light source into electric energy; and
a battery module, coupled to the optical electric conversion module.

11. The optical electric conversion system of claim 10, wherein the battery module includes a plurality of rechargeable batteries.

12. The optical electric conversion system of claim 10, wherein the light guide module includes one or more light guide bodies.

13. The optical electric conversion system of claim 12, wherein the photosensing module includes one or more photosensors and each photosensor is coupled to the light guide body.

14. The optical electric conversion system of claim 10, wherein the light guide module includes a plurality of light guide bodies, and each light guide body is disposed at a different direction.

15. The optical electric conversion system of claim 14, wherein the light guide module further includes an n-sided pyramid, and n is greater than or equal to 3.

16. The optical electric conversion system of claim 15, wherein the n-sided pyramid includes a vertex and n sides, and each light guide body is disposed on each corresponding side.

17. The optical electric conversion system of claim 15, wherein the display module further includes a plurality of direction indicating elements, and each direction indicating element corresponds to an extended direction of each corresponding side.

18. The optical electric conversion system of claim 14, wherein the display module further includes a plurality of direction indicating elements, and each direction indicating element corresponds to a direction of each corresponding light guide body.

19. The optical electric conversion system of claim 10, wherein the light intensity display apparatus further includes a display device driving module for connecting the processing module and the display module.

20. The optical electric conversion system of claim 10, wherein the optical electric conversion system further includes at least one output port.
